(19) United States
(12) Patent Application Publication
(10) Pub. No.: US 2017/0117353 A1
(43) Pub. Date: Apr. 27, 2017

(54) CIRCUIT BOARD AND ELECTRONIC DEVICE

(71) Applicant: NAPRA CO., LTD., TOKYO (JP)

(72) Inventors: Shigenobu SEKINE, TOKYO (JP); Kazutoshi KAMIBAYASHI, TOKYO (JP)

(21) Appl. No.: 14/923,719

(22) Filed: Oct. 27, 2015

(51) Int. Cl. H01L 29/06; H01L 29/41; H01L 29/866

(52) U.S. Cl. CPC H01L 29/0611; H01L 29/866; H01L 29/41

(57) ABSTRACT

Provided is a circuit board which includes a semiconductor substrate, a Zener diode, and a first vertical conductor and a second vertical conductor which configure a paired current path, wherein in the Zener diode, an N-type semiconductor region and a P-type semiconductor region being composed of the semiconductor substrate, with a PN junction extending in the thickness direction of the semiconductor substrate; and the first vertical conductor and the second vertical conductor penetrating the semiconductor substrate in the thickness direction, the first vertical conductor being brought into contact with the N-type semiconductor region, and the second vertical conductor being brought into contact with the P-type semiconductor region.

### BACKGROUND OF THE INVENTION

1. Field of the Invention

This invention relates to a circuit board, and an electronic device using the same.

2. Description of the Related Art

In the field of semiconductor integrated circuit device having a semiconductor element, semiconductor circuit, semiconductor chip and so forth mounted on a circuit board, a trend of development has rapidly shifted from the conventional SMT (Surface Mount Technology)—oriented mounting towards three-dimensional mounting. In particular, driven by increasingly growing demands for downsizing, higher operational speed and lower power consumption, a remarkable progress has been made on three-dimensional SiP (system-in-package) technology which combines SiP, integrating a plurality of LSI-containing systems into one package, with the three-dimensional mounting. SiP is an advantageous technique in terms of lower power consumption, shorter development term, and lower cost. Combination of SiP with the three-dimensional mounting, which enables high-density mounting, will yield three-dimensional electronic devices based on advanced system integration.

There is known TSV (Through Silicon Via) technology as an element technology which supports the three-dimensional mounting described above. Using the TSV technology, it now becomes possible to integrate a large number of functions within a small occupation area, and to increase the processing speed by virtue of dramatically shortened current paths.

JP-A-2010-67916 proposes a semiconductor integrated circuit device which includes a first substrate composed of a semiconductor substrate, and a second substrate; the first substrate having on one surface thereof an active element formed thereon, and having a first through-conductor formed so as to extend therethrough; the second substrate having on one surface thereof a passive element formed thereon, and having a second through-conductor formed so as to extend therethrough; the first substrate and the second substrate are disposed so as to mate the individual other surfaces; and first through-conductor and the second through-conductor being electrically connected.

The semiconductor integrated circuit device is mainly composed of active elements such as semiconductor elements, and may therefore sometimes induce erroneous operation or breakdown of element, due to noises which sustain only for a short time but with a large amplitude value (peak value), such as spike noise, impulse noise and so forth. In particular, the spike noise and impulse noise, ascribed to static electricity and reach even up to tens of thousands of volts, will easily cause such problems.

To supplement the drawbacks of the semiconductor integrated circuit device described above, a variety of elements or circuits for absorbing noise have been developed and put into practical use. The conventional noise absorption technique might be applied to the three-dimensional electronic device which uses the TSV technology.

Every effort of introducing the conventional noise absorption technique into the three-dimensional electronic device, however, means addition of the noise absorption element or the noise absorption circuit, which is eventually against the technical trend of the three-dimensional electronic device aimed at integrating a large number of functions within a small occupation area, shortening the current path, and thereby increasing the processing speed.

### SUMMARY OF THE INVENTION

It is therefore an object of this invention to provide a circuit board which is well adapted to TSV devices strongly oriented to thinning and high-density mounting, and an electronic device using the same.

Note that, “TSV” in the context of the specification of this invention represents a structure in which holes or conductors placed therein extend in the substrate in the thickness (vertical) direction, irrespective whether the holes or the internal conductors penetrate the substrate or not, or irrespective whether a silicon substrate is used or not.

Aimed at solving the problems described above, a circuit board of this invention has a semiconductor substrate, a Zener diode, and a first vertical conductor and a second vertical conductor which configure a paired current path. In the Zener diode, an N-type semiconductor region and a P-type semiconductor region are composed of the semiconductor substrate, with a PN junction 113 extended in the thickness direction of the semiconductor substrate.

The first vertical conductor and the second vertical conductor penetrate the semiconductor substrate in the thickness direction, one of them is brought into contact with the N-type semiconductor region, and the other is brought into contact with the P-type semiconductor region.

In the Zener diode in this invention, the N-type semiconductor region and the P-type semiconductor region are composed of the semiconductor substrate. In other words, the Zener diode may be formed by subjecting a semiconductor substrate, such as silicon substrate, to typical semiconductor processes including impurity doping process or the like. It now becomes possible to obtain a thin circuit board having the Zener diode formed in the semiconductor substrate per se, unlike the case where the Zener diode is mounted on the surface of the semiconductor substrate.

The Zener diode in this invention has a PN junction which extends in the thickness direction of the semiconductor substrate. To the thus-configured Zener diode, one of the first vertical conductor and the second vertical conductor, laid so as to penetrate the semiconductor substrate in the thickness direction, is brought into contact with the N-type semiconductor region, and the other is brought into contact with the P-type semiconductor region. In this way, a circuit board, having the Zener diode composed of the semiconductor substrate and connected between the first vertical conductor and the second vertical conductor, may be obtained.

Preferably, the first vertical conductor and the second vertical conductor pass through the N-type semiconductor region or the P-type semiconductor region. With such configuration, the PN junction will have a three-dimensional structure having the X-dimension and Y-dimension defined around the first vertical conductor and second vertical conductor, assuming the XY plane on the surface of the semiconductor substrate, and the Z-dimension defined in the thickness direction of the semiconductor substrate. This three-dimensional structure successfully prevents the PN junction from damage or breakdown due to spike noise or impulse noise, induced by static electricity or thunder stroke.

The circuit board of this invention is combined with a semiconductor device to configure an electronic device. The semiconductor device is mounted on the circuit board, and electrically connected to one ends of the vertical conductors.

Now, since the circuit board of this invention is configured so as to connect a Zener diode, composed of the semiconductor substrate per se, between the first vertical conductor and the second vertical conductor which configure a paired current path, so that the Zener diode turns ON when a noise exceeding the breakdown voltage of the Zener diode, such as spike noise or impulse noise, were applied between the first vertical conductor and the second vertical conductor which configure the paired current path.

Accordingly, even if spike noise or impulse noise should come in, only a voltage equivalent to the breakdown voltage of the Zener diode is applied to the semiconductor device, so that the semiconductor device will successfully be protected from the spike noise or impulse noise. The semiconductor device is not specifically limited so long as it contains semiconductor element or any article containing the same.

In the circuit board, one preferable example of the semiconductor substrate may be a silicon substrate. The silicon substrate is advantageous in that it is costless, has a long-term operation experience as a semiconductor substrate, and is easy to handle. There is, however, no intention to exclude any other semiconductor substrates including compound semiconductor substrate and so forth.

In a specific embodiment, the semiconductor substrate may be P-type, the N-type semiconductor region may be formed in a columnar shape so as to extend in the thickness direction of the semiconductor substrate, wherein one of the pair of the vertical conductors may pass through the N-type semiconductor region, and the other may pass through the semiconductor substrate. This structure may appear as a simple TSV structure having a pair of vertical conductors allowed to penetrate the silicon substrate in the thickness direction, and can therefore maximize advantages of the TSV structure.

An alternative configuration may be that the semiconductor substrate is N-type, the P-type semiconductor region is formed in a columnar shape so as to extend in the thickness direction of the N-type semiconductor substrate, wherein one of the pair of the vertical conductors may pass through the P-type semiconductor region, and the other may pass through the N-type semiconductor substrate. Also this structure may appear as a simple TSV structure having a pair of vertical conductors allowed to penetrate the silicon substrate in the thickness direction, and can therefore maximize advantages of the TSV structure.

A further practical embodiment contains a plurality of pairs of vertical conductors, wherein the individual pairs are arranged so as to be spaced from each other in plane on the semiconductor substrate. This is intended to cope with a vast number of vertical conductors which serve as interconnects, when system LSI, memory LSI, logic circuit, memory circuit, sensor module or photoelectric module is used as the semiconductor device.

### BRIEF DESCRIPTION OF THE DRAWINGS

FIG. 1 is a cross-sectional view illustrating a part of a circuit board according to this invention.

FIG. 2 is a circuit diagram of the circuit board illustrated in FIG. 1.

FIG. 3 is a partial cross-sectional view of an electronic device using the circuit board illustrated in FIG. 1 and FIG. 2.

FIG. 4 is a circuit diagram of the electronic device illustrated in FIG. 3.

FIG. 5 is a partial cross-sectional view of another embodiment of the circuit board according to this invention.

FIG. 6 is a partial plan view illustrating still another embodiment of the circuit board according to this invention.

FIG. 7 is a cross-sectional view taken along line 7-7 in FIG. 6.

FIG. 8 is a partial plan view illustrating still another embodiment of the circuit board according to this invention.

FIG. 9 is a cross-sectional view taken along line 9-9 in FIG. 8.

FIG. 10 is a drawing illustrating another embodiment of the electronic device according to this invention.

### DESCRIPTION OF THE PREFERRED EMBODIMENTS

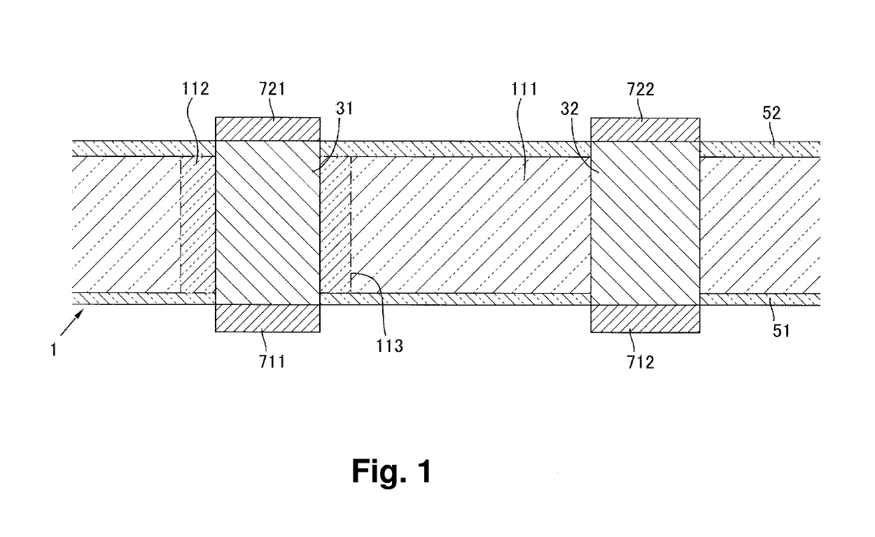

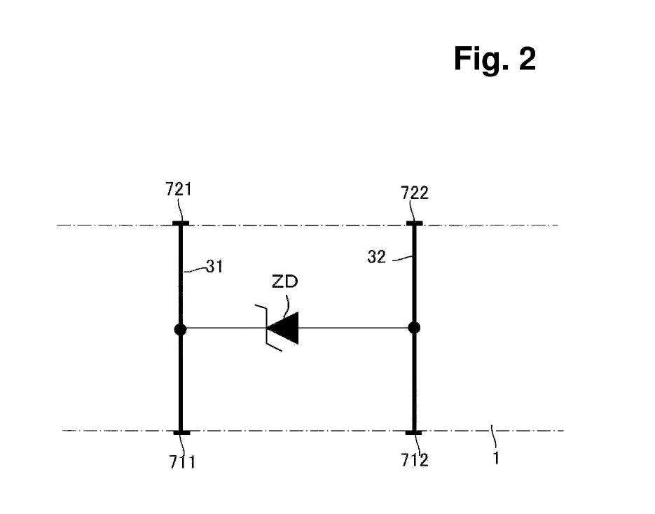

In FIG. 1 to FIG. 10, all identical constituents are given the same or similar reference signs. First, referring to FIG. 1 and FIG. 2, the circuit board according to this invention includes a semiconductor substrate 1, a Zener diode ZD (see FIG. 2), and a first vertical conductor 31 and a second vertical conductor 32 which configure a paired current path. On both surfaces of the semiconductor substrate 1, aligned normal to the direction of the thickness thereof, there are formed insulating films 51, 52. Each of the insulating films 51, 52 is preferably a stacked film of a SiO₂ film and a SiN film. With this configuration, the obtainable insulating film structure will have large adhesion strength and good electric insulation property.

The semiconductor substrate 1 has a shape of flat plate, and is a wafer, or a chip cut out from the wafer. The semiconductor substrate 1 may be composed of silicon (Si), germanium (Ge) or the like, or may be composed of a compound semiconductor such as gallium arsenide (GaAs), gallium nitride (GaN), silicon carbide (SiC) or the like. Among them, silicon substrate is preferable. The silicon substrate is costless, has a long-term operation experience as the semiconductor substrate 1, and is highly reliable. There is, however, no intention to exclude any other semiconductor substrates including compound semiconductor substrate and so forth.

In the Zener diode ZD, a P-type semiconductor region 111 and an N-type semiconductor region 112 are composed of the semiconductor substrate 1. A PN junction 113 thereof extends in the thickness direction of the semiconductor substrate 1. A technique of forming the N-type semiconductor region 112 and the P-type semiconductor region 111 in the semiconductor substrate 1, made of a silicon substrate, is well known. For example, doping of pentavalent phosphorus or arsenic into tetravalent silicon will produce the N-type semiconductor region 112, whereas doping of trivalent boron will produce the P-type semiconductor region 111. The N-type semiconductor region 112 and the P-type semiconductor region 111 are respectively composed of high concentration N-type semiconductor and high concentration P-type semiconductor, with high doses of the impurities exemplified above. In this embodiment, the N-type semiconductor region 112 has an arbitrary columnar shape having a circular, polygonal or other cross-sections, and the P-type semiconductor region 111 spreads around it.

The first vertical conductor 31 and the second vertical conductor 32 which configure the paired current path penetrate the semiconductor substrate 1 in the thickness direction. More specifically, the first vertical conductor 31 is brought into contact with the N-type semiconductor region 112, meanwhile the second vertical conductor 32 is brought into contact with the P-type semiconductor region 111. While the first vertical conductor 31 and the second vertical conductor 32 may be formed by plating, they are more preferably formed by a molten metal filling method by which a molten metal is poured into holes formed in the semiconductor substrate 1, or, by a metal/alloy dispersion filling method by which a metal/alloy dispersion system composed of a metal/alloy fine powder dispersed in a dispersion medium is poured, since these methods can significantly reduce the cost. When the molten metal filling method or the metal/alloy dispersion filling method is employed, the differential pressure filling may be carried out, in such a way that the semiconductor substrate 1 is placed in a vacuum chamber, the chamber is evacuated to reduce the pressure, a conductor material is allowed to flow so as to fill the holes, and the inner pressure of the vacuum chamber is increased again.

In this embodiment, the semiconductor substrate 1 is a high concentration P-type semiconductor substrate, and the high concentration N-type semiconductor region 112 having a columnar form is provided so as to extend through the P-type semiconductor substrate 1 in the thickness direction. Of the first vertical conductor 31 and the second vertical conductor 32, the first vertical conductor 31 passes through the N-type semiconductor region 112, meanwhile the second vertical conductor 32 passes through the high concentration P-type semiconductor substrate 1. This structure appears as a simple TSV structure having the first vertical conductor 31 and the second vertical conductor 32 allowed to penetrate the silicon substrate 1 in the thickness direction, and can therefore maximize advantages of the TSV structure.

In the Zener diode ZD, the N-type semiconductor region 112 and the P-type semiconductor region 111 are composed of the semiconductor substrate 1. Accordingly, the Zener diode ZD may be formed by a typical semiconductor process, such as a process of doping an impurity into the semiconductor substrate 1 composed of a silicon substrate. Therefore, it becomes possible to obtain a thin circuit board having the Zener diode formed in the semiconductor substrate per se, unlike the case where the Zener diode ZD is mounted on the surface of the semiconductor substrate 1.

In the Zener diode ZD in this invention, the PN junction 113 extends in the thickness direction of the semiconductor substrate 1. To the thus-configured Zener diode ZD, the first vertical conductor 31 and second vertical conductor 32, which penetrate the semiconductor substrate 1 in the thickness direction, are provided so that the first vertical conductor 31 comes into contact with the N-type semiconductor region 112, and that the second vertical conductor 32 comes into contact with the P-type semiconductor region 111. In this way, there is obtained a circuit board in which the Zener diode ZD composed of the semiconductor substrate 1 is connected between the first vertical conductor 31 and the second vertical conductor 32 which configure the paired current path.

More specifically, the first vertical conductor 31 and the second vertical conductor 32 penetrate the N-type semiconductor region 112 or P-type semiconductor region 111. With such configuration, the PN junction 113 will have a three-dimensional structure having the X-dimension and Y-dimension defined around the first vertical conductor 31 and second vertical conductor 32, assuming the XY plane on the surface of the semiconductor substrate 1, and the Z-dimension defined in the thickness direction of the semiconductor substrate 1. This three-dimensional structure successfully protects the PN junction from damage or breakdown due to spike noise or impulse noise, induced by static electricity or thunder stroke.

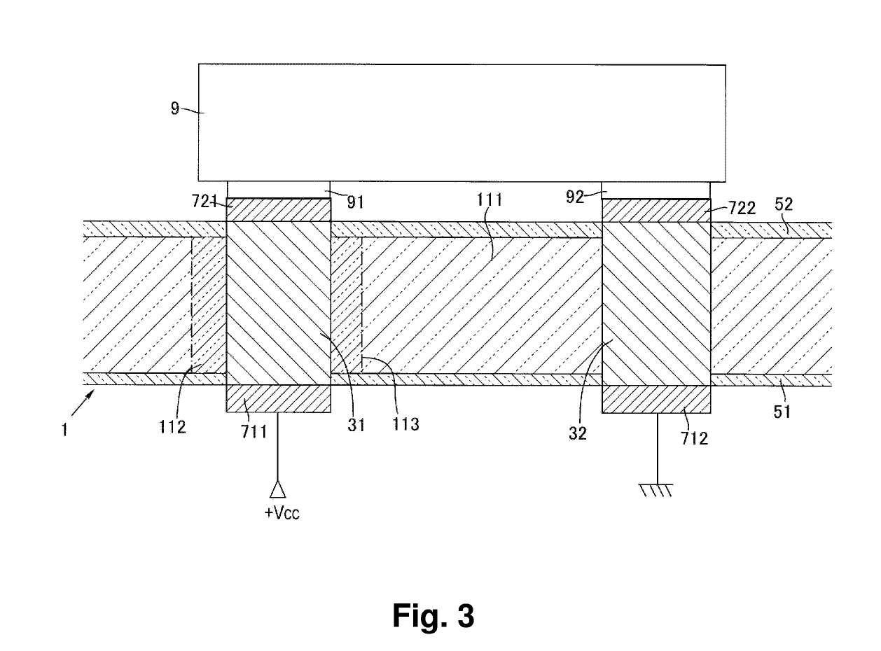

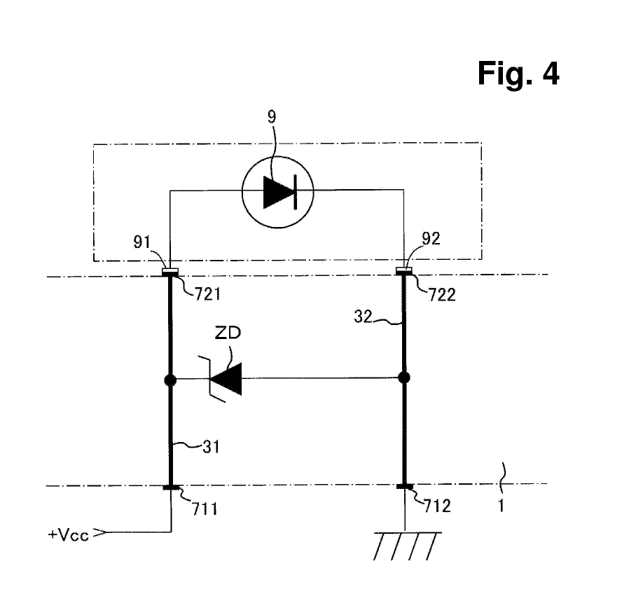

The circuit board of this invention is combined, as illustrated in FIG. 3, with a semiconductor device to configure an electronic device. The semiconductor device 9 is mounted on the circuit board, and is electrically connected to one ends of the first vertical conductor 31 and the second vertical conductor 32. FIG. 3 and FIG. 4 illustrate an exemplary case where a light emitting diode 9 is used as the semiconductor device 9. An anode terminal 91 of the light emitting diode 9 is connected to a power terminal 721 of the first vertical conductor 31 which serves as the cathode of the Zener diode ZD, meanwhile a cathode terminal 92 of the light emitting diode 9 is connected to a ground terminal 722 of the second vertical conductor 32. Source voltage Vcc is applied to a power terminal 711 of the first vertical conductor 31, which resides opposite the power terminal 721. The source voltage Vcc is made constant by a voltage stabilizing function of the Zener diode ZD, and the constant voltage is applied to the light emitting diode 9.

When a noise largely exceeding the breakdown voltage of the Zener diode ZD, such as spike noise or impulse noise, were applied between the first vertical conductor 31 and the second vertical conductor 32, the Zener diode turns ON.

Accordingly, even if spike noise or impulse noise should come in, only a voltage equivalent to the breakdown voltage of the Zener diode ZD is applied to the light emitting device 9 (semiconductor device), so that the light emitting diode 9 will successfully be protected from the spike noise or impulse noise.

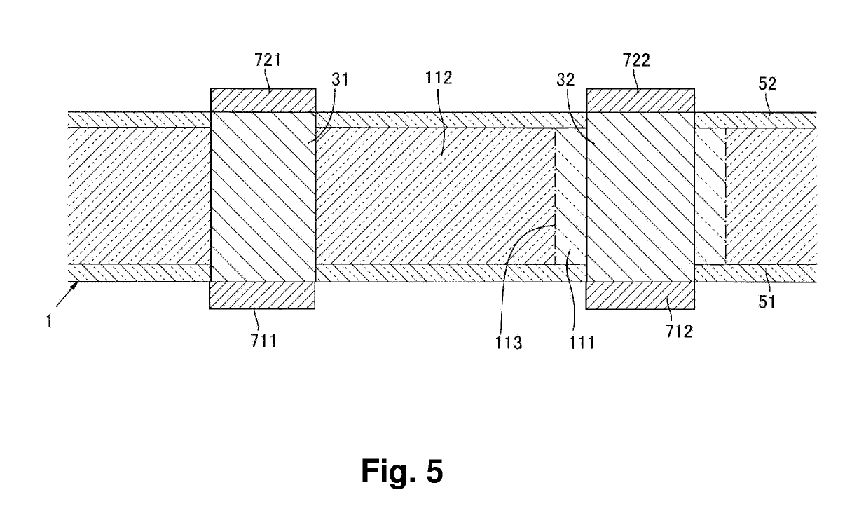

FIG. 5 illustrates another embodiment of the circuit board according to this invention. In this embodiment, unlike the circuit boards illustrated in FIG. 1 to FIG. 4, the semiconductor substrate 1 is an N-type silicon substrate, and the P-type semiconductor region 111 having a columnar form is provided so as to extend through the N-type semiconductor substrate in the thickness direction. Of the first vertical conductor 31 and the second vertical conductor 32 which configure the paired current path, the first vertical conductor 31 passes through the N-type semiconductor substrate 112, meanwhile the second vertical conductor 32 passes through the P-type semiconductor region 111. Also this structure appears as a simple TSV structure having the first vertical conductor 31 and the second vertical conductor 32 allowed to penetrate the silicon substrate in the thickness direction, and can therefore maximize advantages of the TSV structure.

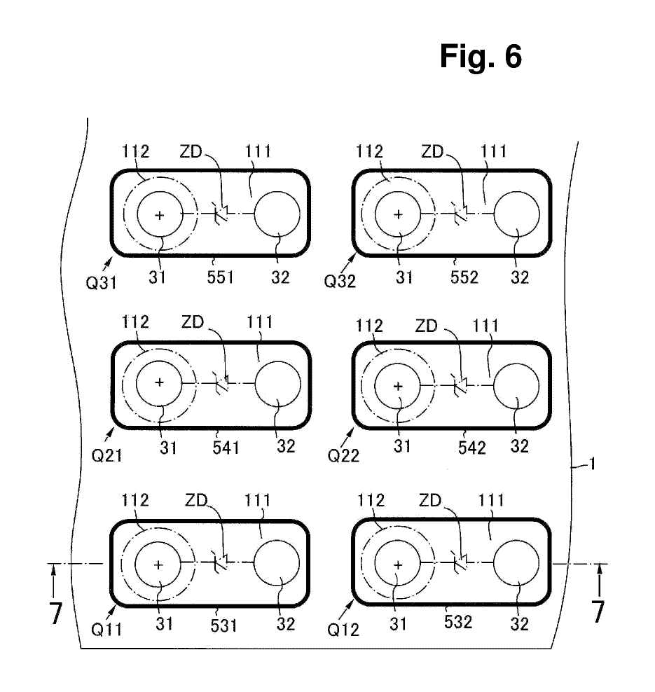

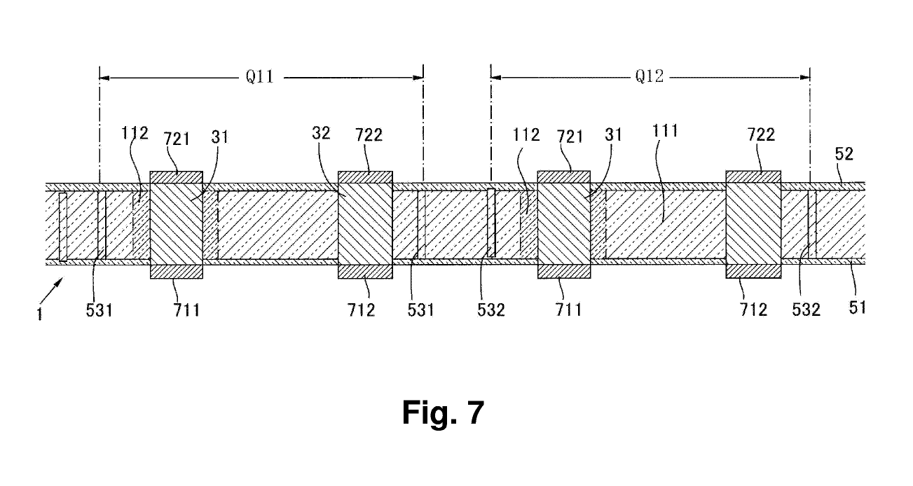

FIG. 6 and FIG. 7 illustrate still another embodiment of the circuit board according to this invention. This embodiment contains a plurality of pairs of vertical conductors (Q11, Q12) to (Q31, Q32), each containing the paired first vertical conductor 31 and second vertical conductor 32, wherein the individual pairs are arranged so as to be spaced from each other in plane on the semiconductor substrate. The individual pairs (Q11, Q12) to (Q31, Q32) are configured so that the first vertical conductor 31, the second vertical conductor 32, the N-type semiconductor region 112 and the P-type semiconductor region 111 are respectively surrounded by ring-patterned insulating layers 531 to 552. In this way, among the individual pairs (Q11, Q12) to (Q31, Q32), mutual interference of the first vertical conductor 31, the second vertical conductor 32, the N-type semiconductor region 112 and the P-type semiconductor region 111 are avoidable. Same as the insulating films 51, 52, each of the insulating layers 531 to 552 may be a stacked film of a SiO₂ film and a SiN film, or may be a cured product of an insulating paste which contains a Si particle and a liquid organic Si compound, filled and then cured in grooves, holes or the like formed in the semiconductor substrate 1 in the thickness direction.

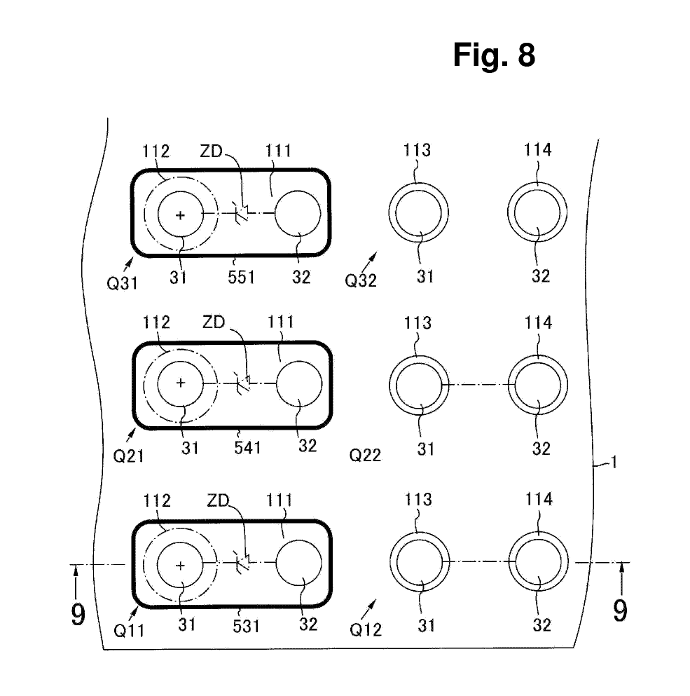

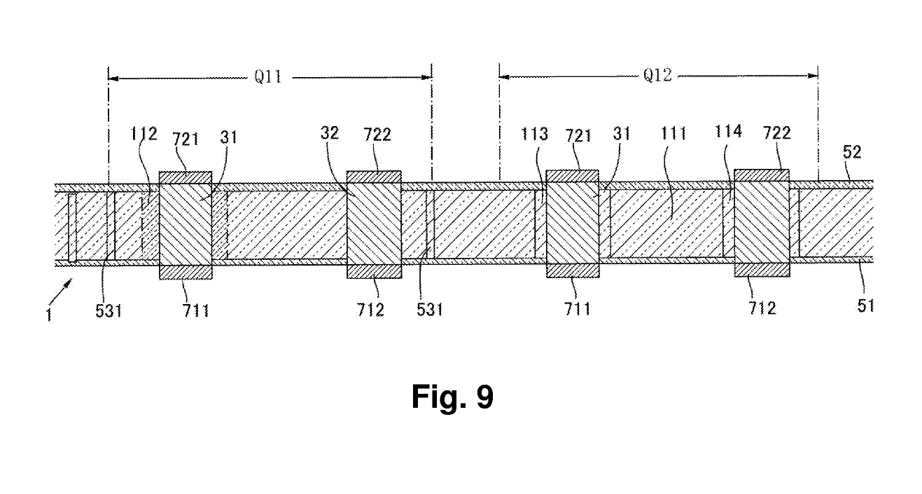

FIG. 8 and FIG. 9 illustrate even another embodiment of the circuit board according to this invention. This embodiment contains a plurality of pairs of vertical conductors (Q11 to Q32), each containing the paired first vertical conductor 31 and second vertical conductor 32, wherein the individual pairs are arranged so as to be spaced from each other in plane on the semiconductor substrate. Of the individual pairs (Q11 to Q32), each of the pairs (Q11, Q21, Q31) is configured so that the first vertical conductor 31, the second vertical conductor 32, the N-type semiconductor region 112 and the P-type semiconductor region 111 are surrounded by ring-patterned insulating layers 531, 541, 551.

Meanwhile, in each of the pairs (Q12, Q22, Q32), the first vertical conductor 31 is surrounded by an insulating layer 113, and the second vertical conductor 32 is surrounded by an insulating layer 114.

Same as the insulating films 51, 52, each of the insulating layers 113, 114 may be a stacked film of a SiO₂ film and a SiN film, or may be a cured product of an insulating paste which contains a Si particle and a liquid organic Si compound, filled and then cured in grooves, holes or the like formed in the semiconductor substrate 1 in the thickness direction.

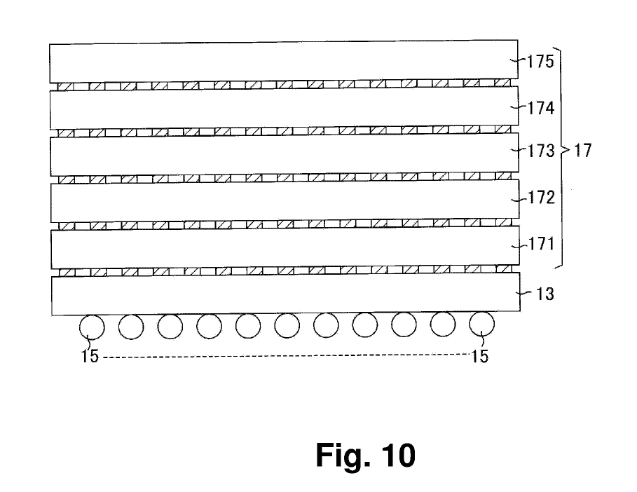

Each of the circuit boards illustrated in FIG. 6 to FIG. 9 may be used typically as a constituent of a three-dimensionally stacked electronic device illustrated in FIG. 10. The three-dimensionally stacked electronic device illustrated in FIG. 10 is configured so that, on an interposer 13 having a ball grid 15, a stack 17 of a plurality of semiconductor chips 171 to 175 is mounted. Quantity of the semiconductor chips 171 to 175 is arbitrary. The circuit board according to this invention is applicable not only to the interposer 13, but also to the semiconductor chips 171 to 175. The semiconductor chips 171 to 175 include a wide variety of electronic parts which are labile to spike noise or impulse noise, as a result of incorporation of semiconductor elements such as system LSI, memory LSI, logic circuit, memory circuit, sensor module or photoelectric module.

As described previously, according to this invention, there is provided a circuit board which is well adapted to TSV devices strongly oriented to thinning and high-density mounting, and an electronic device using the same.

This invention has been described above in detail with reference to, but not limited to, preferred embodiments. It is, however, obvious that those skilled in the art could devise various modifications of the invention based on the technical concepts underlying the invention and teachings disclosed herein.

1. A circuit board comprising:
a semiconductor substrate,
a Zener diode including a PN junction comprising an N-type semiconductor region and a P-type semiconductor region in the semiconductor substrate, and
a first vertical conductor and a second vertical conductor each formed in the semiconductor substrate and configure to form a paired current path, the first and second vertical conductors penetrating the semiconductor substrate in a thickness direction,
the N-type semiconductor region and the P-type semiconductor region being formed from the one surface of the semiconductor substrate to another surface of the semiconductor substrate and configured to surround the first vertical conductor and the second vertical conductor,
the PN junction extending in the thickness direction of the semiconductor substrate and being formed in a three-dimensional structure surrounding either the first vertical conductor or the second vertical conductor,
one of the N-type semiconductor region and the P-type semiconductor region, which surrounds one of the first and second vertical conductors, is formed in a columnar shape so as to extend in the thickness direction of the semiconductor substrate, and
one of the first and second vertical conductors being brought into contact with the N-type semiconductor region of the PN junction in the semiconductor substrate, and the other of the first and second vertical conductors being brought into contact with the P-type semiconductor region of the PN junction in the semiconductor substrate.

2. The circuit board according to claim 1, wherein the first vertical conductor and the second vertical conductor penetrate the N-type semiconductor region or the P-type semiconductor region.

3. An electronic device comprising:
the circuit board of claim 1; and
a semiconductor device, the semiconductor device being mounted on the circuit board, and electrically connected to respective ends of the first and second vertical conductors.

4. An electronic device comprising:
the circuit board of claim 2; and
a semiconductor device, the semiconductor device being mounted on the circuit board, and electrically connected to respective ends of the first and second vertical conductors.

5. The circuit board according to claim 1, further comprising:
an insulating layer surrounding the PN junction and the first and second vertical conductors and penetrating the semiconductor substrate in the thickness direction, the insulating layer electrically insulating an inner area of the semiconductor substrate surrounded by the insulating layer from an outside area of the insulating layer.

6. The circuit board according to claim 5, further comprising:
at least a pair of third and fourth vertical conductors penetrating the semiconductor substrate in the thickness direction; and
additional insulating layers penetrating the semiconductor substrate in the thickness direction, and respectively surrounding each of the third and fourth vertical conductors.

7. The circuit board according to claim 5, wherein the insulating layer is ring-shaped in plan view.

8. The circuit board according to claim 6, wherein each of the insulating layers is ring-shaped in plan view.
